(19) United States
(12) Patent Application Publication
(10) Pub. No.: US 2026/0304650 A1
(43) Pub. Date: Oct. 1, 2026

(54) SMOOTH LATCHING TO MITIGATE WIRE DAMAGE

(71) Applicant: Schneider Electric USA, Inc., Andover, MA (US)

(72) Inventor: José Martín Hernández Ramírez, Andover, MA (US)

(73) Assignee: Schneider Electric USA, Inc., Boston, MA (US)

(21) Appl. No.: 19/094,021

(22) Filed: Mar. 28, 2025

(51) Int. Cl. H05K 5/02; H02B 1/30; H02B 1/38; H02B 1/46

(52) U.S. Cl. CPC H05K 5/0221; H02B 1/306; H02B 1/38; H02B 1/46

(57) ABSTRACT

A system includes a latch with a first surface that is planar. A rotation axis is defined in a direction extending normal to the first surface. A wedge surface extends in a first direction from the first surface to a second surface. The wedge surface extends circumferentially in a second direction. The first surface extends radially away from the rotation axis to further extent than does the second surface so the wedge surface is oblique relative to the rotation axis. A handle is engaged to the latch for rotation of the handle and the latch together around the rotation axis. The system includes a door, wherein the handle and the latch are engaged on opposite sides of the door for rotation relative to the door. The first surface of the latch is parallel to a planar interior surface of the door.

### BACKGROUND

### 1. Field

The present disclosure relates to latching mechanisms, and more particularly to latching mechanisms such as used in doors of electrical panels, e.g., breaker boxes.

### 2. Description of Related Art

Typical electrical panels or breaker boxes have doors that latch against the lateral frame or threshold of the panel box. The latching component traditionally swings through a circular arc to engage or clear the lateral frame as needed to open or close the door. In improper use, it is possible for stray electrical wires to be pinched between the latching component and the panel box when closing the latching mechanism. This it typically mitigated by moving the wires out of the way manually during installation, however if not mitigated the repeated use of a traditional latch could theoretically begin to degrade the pinched wires.

The conventional techniques have been considered satisfactory for their intended purpose. However, there is an ever-present need for improved systems and methods for latching doors such as in electrical panels, which mitigate pinching of wires. This disclosure provides a solution for this need.

### SUMMARY

A latch mechanism includes a latch with a first surface that is planar and configured to move in a rotation plane parallel to a planar interior surface of a door of an electrical panel. A rotation axis is defined in a direction extending normal to the first surface for rotation of the latch about the rotation axis. A second surface opposite the first surface. The rotation axis extends through the second surface. The latch has a third surface on a first side connecting from the first surface to the second surface. A fourth surface is on a second side opposite the first side, connecting from the first surface to the second surface. A wedge surface extends in a first direction from the first surface to the second surface, and extends in a second direction from the third surface to the fourth surface. The first surface extends radially away from the rotation axis to a further extent than does the second surface so the wedge surface is oblique relative to the rotation axis.

The wedge surface can converge conically toward the rotation axis as it extends away from the first surface. The wedge surface can be contoured in a circumferential direction about the rotation axis. The wedge surface can have a concave radial cross-section extending from the third surface to the fourth surface. The radial cross-section can include an angular step separating two surface portions of the wedge surface.

A back surface of the latch can be opposite the wedge surface. The back surface can extend from the first surface to the second surface, and can extend from the third surface to the fourth surface. A bore can be defined through the latch along the rotation axis. A first countersink can extend from the first surface to the bore. A second countersink can extend from the second surface to the bore. The first countersink and the second countersink can be configured to receive fastener components for engaging the latch to a rotatable handle of an electrical panel door. A pair of protrusions can extend from the first surface to facilitate making two points of contact between the latch and a threshold.

A system includes a latch mechanism having a latch with a first surface that is planar. A rotation axis is defined in a direction extending normal to the first surface. A second surface is opposite the first surface. The rotation axis extends through the second surface. A wedge surface extends in a first direction from the first surface to the second surface. The wedge surface extends circumferentially in a second direction. The first surface extends radially away from the rotation axis to further extent than does the second surface so the wedge surface is oblique relative to the rotation axis. A handle is engaged to the latch for rotation of the handle and the latch together around the rotation axis. The system includes a door, wherein the handle and the latch are engaged to the door on opposite sides of the door for rotation relative to the door about the rotation axis. The first surface of the latch is parallel to a planar interior surface of the door.

A box of an electrical panel can be included. The door can be hingedly connected to the box. The door can be configured to move between an open position and a closed position. In the open position, the door can be positioned away from a threshold of the box allowing access to circuit devices of the box. In the closed position, the door can closely engage the threshold of the box to separate the circuit devices from an exterior space of the box.

The handle and the latch can be rotatably connected to the door to rotate relative to the door between a first position and a second position. In the first position, the latch can clear the threshold of the box regardless of whether the door is in the open position or in the closed position, allowing opening and closing of the door. In the second position, the latch can engage the threshold of the box with the door in the closed position to prevent opening the door without first rotating the handle and the latch into the first position. With the door in the closed position and with the handle and the latch in the second position, the first surface of the latch can engage an inward facing surface of the threshold of the box.

The latch can be configured to sweep a volumetric path between the first position and the second position. With the door in the closed position and the latch in the first position, if there are any wires of the box extending through the volumetric path, the wedge surface can be configured to move the wires away from the threshold of the box as the latch rotates from the first position to the second position so the wires are not pinched between the latch and the box. The handle can predominantly move toward a hinge connecting the door to the box with the handle rotating from the second position to the first position. The handle can include a lock configured to lock the handle and the latch in the second position in a locked state, and to allow rotation of the handle and the latch in an unlocked state.

A method includes a latch sweeping a volumetric path with rotation of the latch from a first position to a second position about a rotation axis. In the first position, the latch clears a threshold of a box of an electrical panel. In the second position, the latch engages the threshold. The method includes a wedging surface of the latch clearing wires out of the volumetric path to avoid pinching wires between the latch and the threshold.

The latch can be engaged to a door of the electrical panel for rotation relative to the door about the rotation axis. The latch can sweep the volumetric path with the door in a closed position relative to the threshold of the box. With the door in the closed position and the latch in the second position, the latch can prevent opening the door without the latch first rotating into the first position. The latch can sweep the volumetric path keeping a first surface of the latch parallel to a planar interior surface defined by the plane of the door.

These and other features of the systems and methods of the subject disclosure will become more readily apparent to those skilled in the art from the following detailed description of the disclosed embodiments taken in conjunction with the drawings.

### BRIEF DESCRIPTION OF THE DRAWINGS

So that those skilled in the art to which the subject disclosure appertains will readily understand how to make and use the devices and methods of the subject disclosure without undue experimentation, embodiments thereof will be described in detail herein below with reference to certain figures, wherein:

FIG. 1 is a perspective view of an embodiment of a system constructed in accordance with the present disclosure, showing the electrical panel box with the door closed and the handle in the latching position;

FIG. 2 is a perspective view of the system of FIG. 1, showing the door in the open position;

FIG. 3 is a perspective view of the system of FIG. 2, showing the deadfront removed from the box;

FIGS. 4-11 are perspective, top plan, bottom plan, back end elevation, right side-elevation, left-side elevation, front end elevation, and cross-sectional right-side elevation views, respectively, of a portion of the system of FIG. 1, showing the surfaces of the latch;

FIGS. 12-14 are perspective, top plan, and cross-sectional right-side elevation views, respectively, of another configuration of a latch of the system of FIG. 1, showing a step in the cross-sectional profile of the wedging surface;

FIG. 15 is a perspective view of a portion of the system of FIG. 1, showing a pocket portion of the deadfront;

FIG. 16 is a perspective view of a portion of the system of FIG. 1, showing the engagement of the latch with the inner surface of the door;

FIG. 17 is a front elevation view of a portion of the system of FIG. 1, schematically showing the latch in the first, unlatched position without the handle or door shown;

FIG. 18 is a bottom cross-sectional elevation view of the system of FIG. 17, showing a wire in the volumetric path of the latch;

FIG. 19 is a front end elevation view of the system of FIG. 17, schematically showing the latch in the second, latching position without the handle or door shown; and

FIG. 20 is a bottom-cross-sectional elevation view of the system of FIG. 17, schematically showing the latch moving the wire away from the threshold of the box.

### DETAILED DESCRIPTION

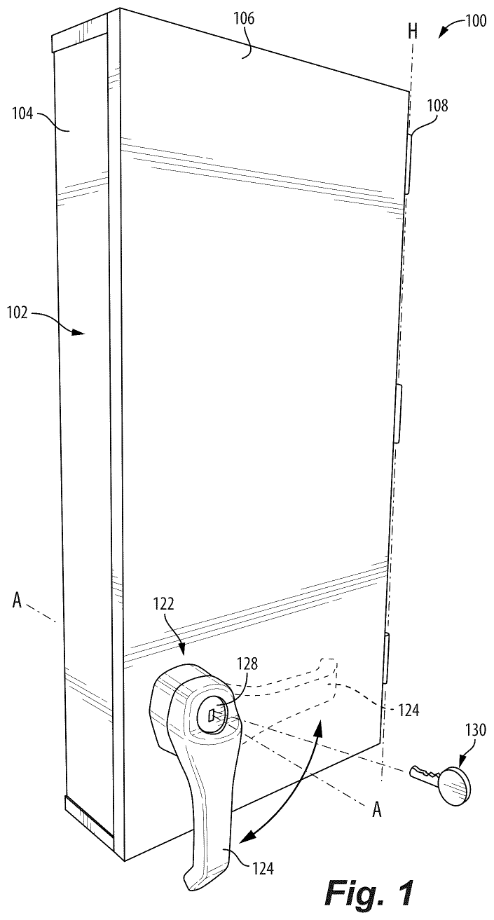

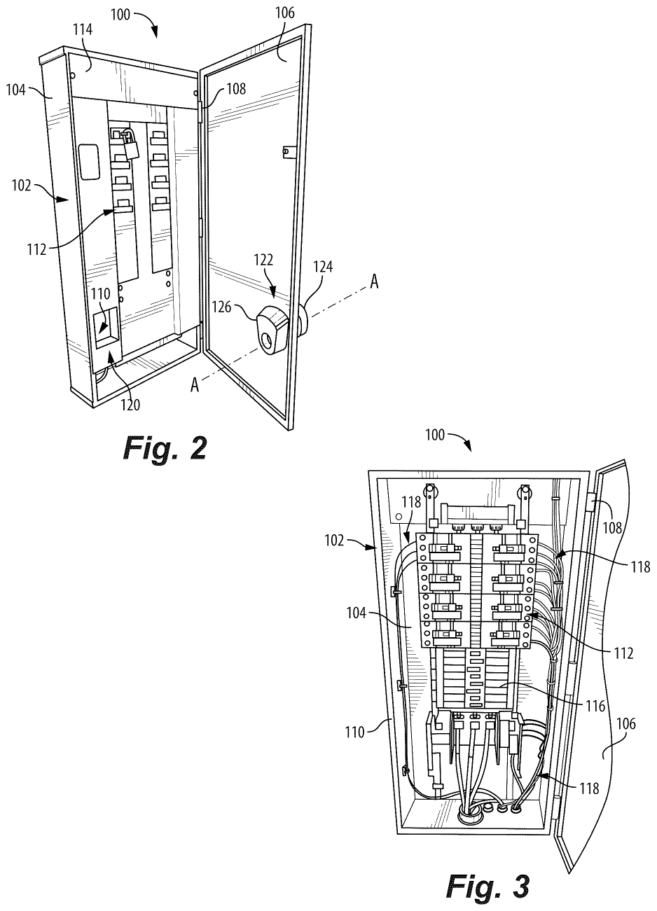

Reference will now be made to the drawings wherein like reference numerals identify similar structural features or aspects of the subject disclosure. For purposes of explanation and illustration, and not limitation, a partial view of an embodiment of a system in accordance with the disclosure is shown in FIG. 1 and is designated generally by reference character 100. Other embodiments of systems in accordance with the disclosure, or aspects thereof, are provided in FIGS. 2-20, as will be described. The systems and methods described herein can be used to provide smooth latching, e.g., mitigating pinching wires, in latches of electrical panels.

System 100 includes an electrical panel 102, which includes a box 104 with a door 106 mounted to the box by a hinge 108. The door 106 is configured to move between an open position and a closed position relative to the box 104 by rotation about the axis H of the hinge 108. In the open position, shown in FIG. 2, the door 106 is positioned away from a threshold 110 of the box 104, allowing access to circuit devices 112, e.g., circuit breakers, of the box 104. In the closed position, shown in FIG. 1, the door 106 closely engages the threshold 110 (labeled in FIGS. 2-3) of the box 104 to enclose the circuit devices 112, separating them from an exterior space of the box 104. The electrical panel 102 includes a deadfront 114, shown installed in FIG. 2, and shown removed from the box 104 in FIG. 3. When installed, the deadfront 114 covers over an interior 116 and wires 118 within the interior space of the box 104. A pocket 120 in the deadfront 114 allows access to the threshold 110 of the box 104 through the outward facing surface of the deadfront 114.

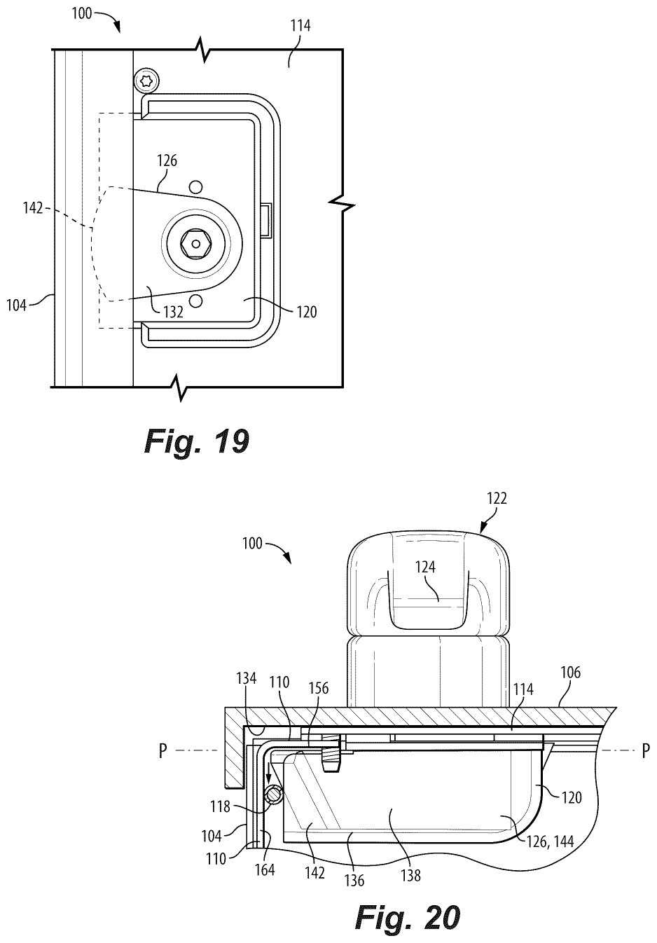

A latch mechanism 122 includes a handle 124 (labeled in FIGS. 1-2) and a latch 126 (labeled in FIG. 2), which can be of metal, polymer, or any other suitable material. The handle 124 is engaged to the latch 126 for rotation of the handle 124 and the latch 126 together around the rotation axis A, labeled in FIG. 1. The handle 124 and the latch 126 are engaged to the door 106 on opposite sides of the door 106, as shown in FIG. 2, for rotation relative to the door 106 about the rotation axis A. The handle 124 and the latch 126 are rotatably connected to the door 106 to rotate about the axis A relative to the door 106 between a first position, shown in FIG. 2, and a second position, shown in FIG. 1. FIG. 1 shows the handle 124 in the first position in broken lines. In the first position (or unlatched position), the latch 126 clears the threshold 110 of the box 104 regardless of whether the door 106 is in the open position or in the closed position, allowing opening and closing of the door 106. In the second position (or latching position), the latch 126 engages the threshold 110 of the box 104 (as shown in FIGS. 19-20) with the door 106 in the closed position to prevent opening the door 106 without first rotating the handle 124 and the latch 126 into the first position. If the latch 126 is in the second, latching position when the door 106 is in the open position, as shown in FIG. 16, the handle 124 and latch 126 should be returned to the first, unlatched position before closing and latching the door 106.

With reference again to FIG. 1, the handle 124 predominantly moves toward the hinge 108 when the handle 124 rotates from the second, latching position to the first, unlatched position, e.g., to open the door 106, e.g., the majority of the length or mass of the handle 124 moves toward from the hinge 108. The handle 124 can optionally include a lock 128 configured to lock the handle 124 and the latch 126 in the second, latching position in a locked state, and to allow rotation of the handle 124 and the latch 126 in an unlocked state, e.g., where locking and unlocking uses a key 130.

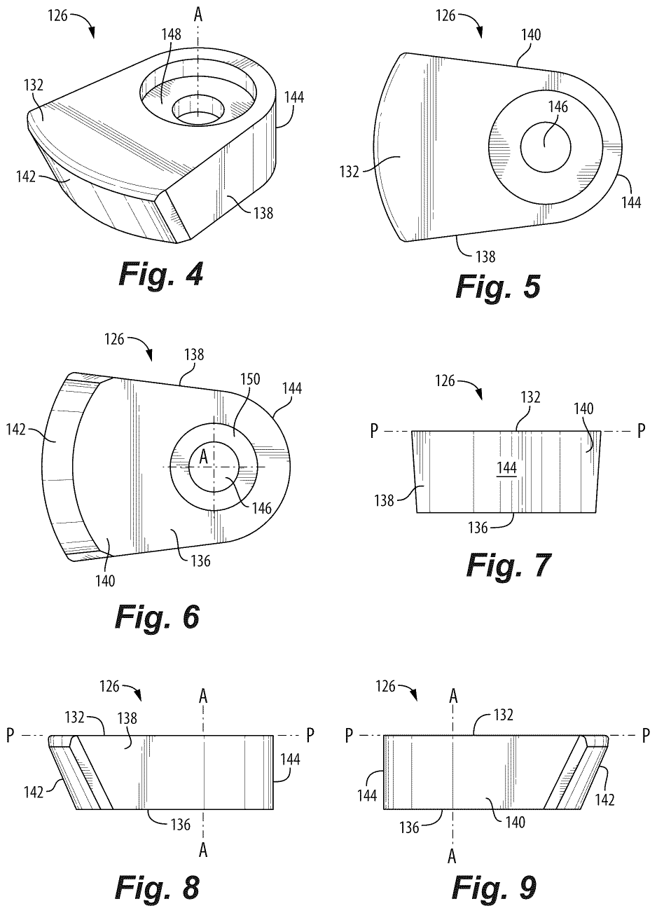

Referring now to FIG. 4, the latch 126 has a first surface 132 that is planar and configured to move in a rotation plane P (labeled in FIGS. 8-11) parallel to a planar interior surface 134 (labeled in FIG. 16) of the door 106. The rotation axis A (labeled in FIG. 11) is defined in a direction extending normal to the first surface 132. A second surface 136, labeled in FIGS. 8-9, of the latch 126 is opposite the first surface 132. The rotation axis A extends through the second surface. The latch 126 has a third surface 138 on a first side connecting from the first surface 132 to the second surface 136, as shown in FIG. 8. A fourth surface 140 is on a second side opposite the first side of the latch 126 as shown in FIG. 9, connecting from the first surface 132 to the second surface 136.

Referring again to FIG. 4, a wedge surface 142 extends in a first direction, e.g., generally vertically as oriented in FIGS. 8 and 9, from the first surface 132 to the second surface 136. The wedge surface 142 extends in a second direction, circumferentially around the rotation axis A, from the third surface 138 to the fourth surface 140, as shown in FIG. 6. As shown in FIGS. 8-9, the first surface 132 extends radially away from the rotation axis A to a further extent than does the second surface 136, so the wedge surface 142 is oblique relative to the rotation axis A.

As shown in FIG. 4, the wedge surface 142 converges conically toward the rotation axis A as it extends away from the first surface 132, i.e., the wedge surface 142 converges toward the rotation axis A in the downward direction as oriented in FIG. 4 and wraps partially around the rotation axis A in the circumferential direction. As shown in FIG. 6, the wedge surface 142 is contoured, e.g., curved, in the circumferential direction about the rotation axis A, but does not necessarily have to follow a circular contour.

As shown in FIG. 7, a back surface 144 of the latch is opposite the wedge surface 142. The back surface 144 extends from the first surface 132 to the second surface 136 as shown in FIGS. 8-9, and extends from the third surface 138 to the fourth surface 140, as shown in FIGS. 5-6. The back surface 144 can extend circumferentially around the rotation axis A and can optionally be tangential with the third surface 138 and the fourth surface 140 as shown in FIGS. 5-6.

With reference now to FIG. 5, an opening or bore 146 is defined through the latch 126 along the rotation axis A. As shown in FIG. 11, a first countersink 148 extends from the first surface 132 to the bore 146, e.g., inset from the surrounding portion of the first surface 132. A second countersink 150 extends from the second surface 136 to the bore 146, also shown in FIG. 11, e.g., inset from the surrounding portion of the second surface 136. The first countersink 148 and the second countersink 150 are configured to receive fastener components 152, labeled in FIG. 16, for engaging the latch 126 to the rotatable handle 124 of FIG. 1.

FIGS. 12, 13, and 14 show the same latch configuration as FIGS. 4, 6, and 11, respectively, but with a different wedge surface configuration. The wedge surface 142 in FIGS. 12-14 has a concave radial cross-section relative to the rotation axis A, e.g., the cross-section shown in FIG. 14, extending from the first surface 132 to the second surface 136, so the two surface portions of the wedge surface 142 in FIG. 12 are set in deeper into the body of the latch 126 than is the wedge surface 142 of FIG. 1. This concave radial cross-section includes an angular step 154 separating two surface portions of the wedge surface 142 at a hard angle.

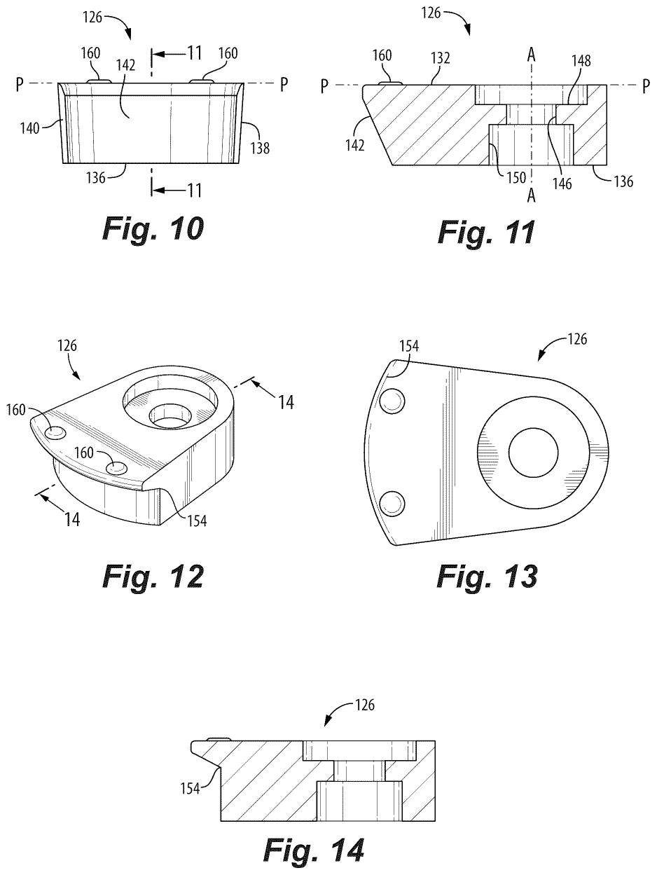

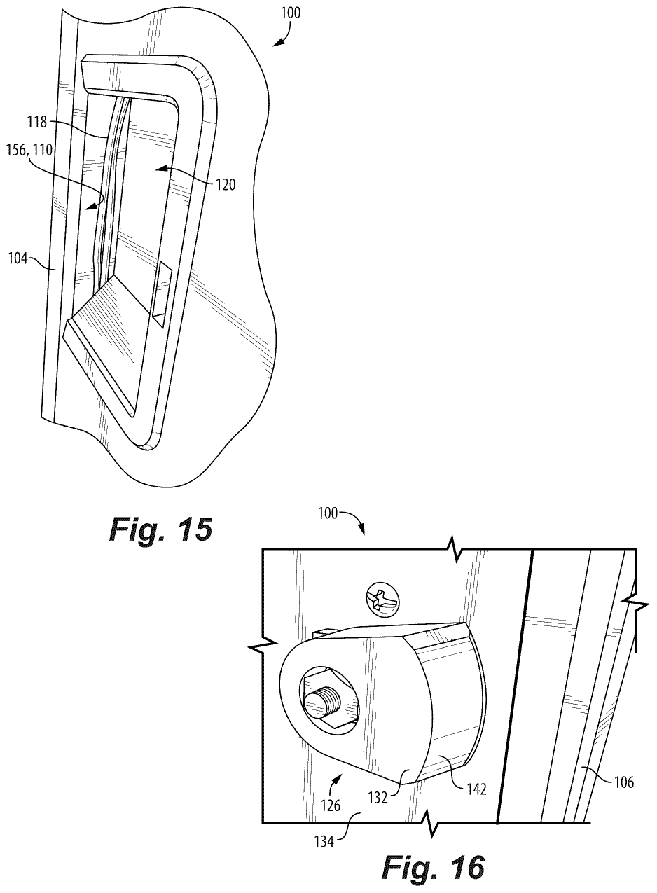

With reference now to FIG. 15, the first surface 132 of the latch 126 (labeled in FIG. 4) is parallel to a planar interior surface 134 (labeled in FIG. 16) of the door 106. As shown in FIG. 10, optional bumper protrusions 160 from the first surface 132 can facilitate making two points of contact between the latch 126 and the planar interior surface 156 of the threshold 110 (labeled in FIGS. 18 and 20), even if the inward facing surface 156 of the threshold 110 is not perfectly square to the door 106, latch 126, and rest of the box 104. With the door 106 in the closed position and with the handle 124 and the latch 126 in the second position, as shown in FIG. 1, the first surface 132 (labeled in FIG. 4) of the latch 126 engages an inward facing surface 156 of the threshold 110 of the box. In some instances, e.g., instances of improper installation of the wires 118 and/or the deadfront 114, one or more wires 118 can extend through the pocket 120 of the deadfront 114, in the same space where the latch 126 operates.

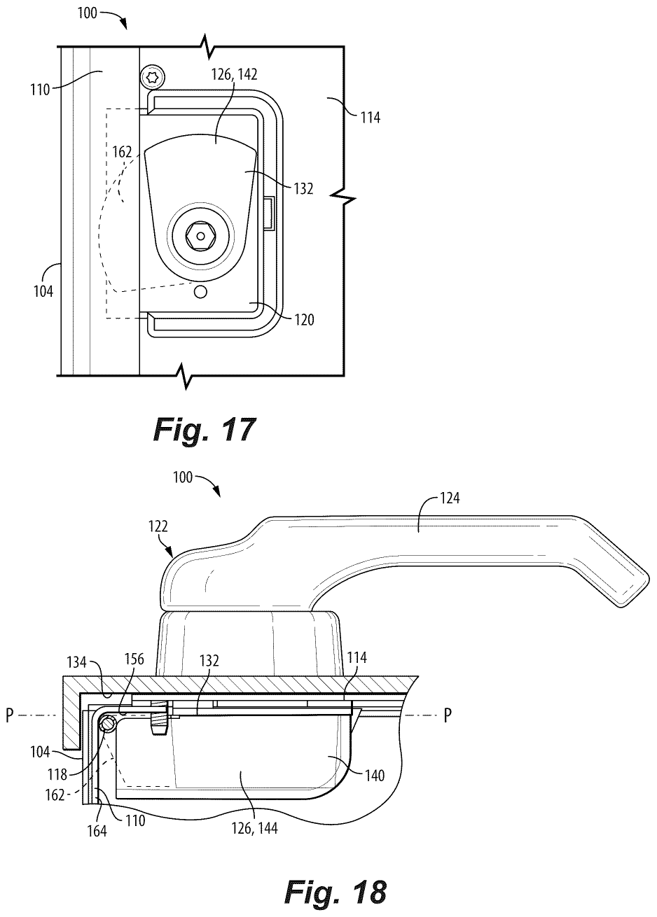

With reference now to FIGS. 17 and 18, the system 100 is shown with the door 106 in the closed position, and the latch mechanism 122 in the first, unlatched position. FIG. 17 shows the system 100 with the door 106 removed for sake of showing the latch 126. As FIG. 18 shows, one or more wires 118 are in the pocket 120 of the deadfront 114 with the latch 126. The latch 126 is configured to sweep a volumetric path 162 when the latch 126 rotates between the first position of FIGS. 17-18 into the second position of FIGS. 19-20, which correspond to FIGS. 17-18, respectively, but for the position of the latch mechanism 122. With the door 106 in the closed position and the latch 126 in the first position, if there are any wires 118 of the box 104 extending through the volumetric path 162, the wedge surface 142 (labeled in FIG. 20) is configured to move the wire or wires 118 away from the threshold 110 of the box 104 as the latch 126 rotates from the first position to the second position, as indicated by the movement arrow in FIG. 20, so the wire or wires 118 are not pinched between the latch 126 and the box 104, e.g. between the latch 126 and the inward facing surface 156 of the threshold 110, or the adjacent lateral inward facing surface 164 of the box 104. Avoiding pinching wires 118 can help avoid degrading the wires 118 by operation of the latch 126. The latch 126 sweeps the volumetric path 162 while keeping a first surface 132 of the latch 126 parallel to a planar interior surface 134 defined by the plane of the door 106.

The methods and systems of the present disclosure, as described above and shown in the drawings, provide for mitigating pinching of wires by latches of electrical panel doors. While the apparatus and methods of the subject disclosure have been shown and described with reference to certain embodiments, those skilled in the art will readily appreciate that changes and/or modifications may be made thereto without departing from the scope of the subject disclosure.

What is claimed is:

1. A latch mechanism comprising:
a latch including:
a first surface that is planar and configured to move in a rotation plane parallel to a planar interior surface of a door of an electrical panel, wherein a rotation axis is defined extending normal to the first surface for rotation of the latch about the rotation axis;
a second surface opposite the first surface, wherein the rotation axis extends through the second surface;
a third surface on a first side connecting from the first surface to the second surface;
a fourth surface on a second side opposite the first side, connecting from the first surface to the second surface; and
a wedge surface extending in a first direction from the first surface to the second surface, and extending in a second direction from the third surface to the fourth surface,
wherein the first surface extends radially away from the rotation axis to a further extent than does the second surface so the wedge surface is oblique relative to the rotation axis.

2. The latch mechanism as recited in claim 1, wherein the wedge surface converges conically toward the rotation axis as it extends away from the first surface.

3. The latch mechanism as recited in claim 1, wherein the wedge surface is contoured in a circumferential direction about the rotation axis.

4. The latch mechanism as recited in claim 3, wherein the wedge surface has a concave radial cross-section extending from the third surface to the fourth surface.

5. The latch mechanism as recited in claim 4, wherein the radial cross-section includes an angular step separating two surface portions of the wedge surface.

6. The latch mechanism as recited in claim 1, further comprising a pair of protrusions extending from the first surface to facilitate making two points of contact between the latch and a threshold.

7. The latch mechanism as recited in claim 1, further comprising a back surface opposite the wedge surface, wherein the back surface extends from the first surface to the second surface, and extends from the third surface to the fourth surface.

8. The latch mechanism as recited in claim 1, wherein a bore is defined through the latch along the rotation axis.

9. The latch mechanism as recited in claim 8, further comprising:
a first countersink extending from the first surface to the bore; and
a second countersink extending from the second surface to the bore, wherein the first countersink and the second countersink are configured to receive fastener components for engaging the latch to a rotatable handle of an electrical panel door.

10. A system comprising:
a latch mechanism including:
a latch having a first surface that is planar, wherein a rotation axis is defined extending normal to the first surface, a second surface opposite the first surface, wherein the rotation axis extends through the second surface, and a wedge surface extending in a first direction from the first surface to the second surface, and extending circumferentially around the rotation axis in a second direction, wherein the first surface extends radially away from the rotation axis to further extent than does the second surface so the wedge surface is oblique relative to the rotation axis; and
a handle engaged to the latch for rotation of the handle and the latch together around the rotation axis; and
a door, wherein the handle and the latch are engaged to the door on opposite sides of the door for rotation relative to the door about the rotation axis, with the first surface of the latch parallel to a planar interior surface of the door.

11. The system as recited in claim 10, further comprising:
a box of an electrical panel, wherein the door is hingedly connected to the box with an open position wherein the door is positioned away from a threshold of the box allowing access to circuit devices of the box, and a closed position wherein the door closely engages the threshold of the box to separate the circuit devices from an exterior space of the box.

12. The system as recited in claim 11, wherein the handle and the latch are rotatably connected to the door to rotate relative to the door between:
a first position wherein the latch clears the threshold of the box regardless of whether the door is in the open position or in the closed position, allowing opening and closing of the door; and
a second position where the latch engages the threshold of the box with the door in the closed position to prevent opening the door without first rotating the handle and the latch into the first position.

13. The system as recited in claim 12, wherein with the door in the closed position and with the handle and the latch in the second position, the first surface of the latch engages an inward facing surface of the threshold of the box.

14. The system as recited in claim 12, wherein the latch is configured to sweep a volumetric path between the first position and the second position, wherein with the door in the closed position and the latch in the first position, and with wires of the box extending through the volumetric path, the wedge surface is configured to move the wires away from the threshold of the box as the latch rotates from the first position to the second position so the wires are not pinched between the latch and the box.

15. The system as recited in claim 14, wherein the handle predominantly moves toward a hinge connecting the door to the box with the handle rotating from the second position to the first position.

16. The system as recited in claim 14, wherein the handle includes a lock configured to lock the handle and the latch in the second position in a locked state, and to allow rotation of the handle and the latch in an unlocked state.

17. A method comprising:
a latch sweeping a volumetric path with rotation of the latch from a first position to a second position about a rotation axis, wherein in the first position, the latch clears a threshold of a box of an electrical panel, and wherein in the second position, the latch engages the threshold; and
a wedging surface of the latch clearing wires out of the volumetric path to avoid pinching wires between the latch and the threshold.

18. The method as recited in claim 17, wherein the latch is engaged to a door of the electrical panel for rotation relative to the door about the rotation axis.

19. The method as recited in claim 18, wherein the latch sweeps the volumetric path with the door in a closed position relative to the threshold of the box, wherein with the door in the closed position and the latch in the second position, the latch prevents opening the door without the latch first rotating into the first position.

20. The method as recited in claim 18, wherein the latch sweeps the volumetric path keeping a first surface of the latch parallel to a planar interior surface defined by the plane of the door.
